(19) United States
(12) Patent Application Publication
(10) Pub. No.: US 2023/0299029 A1
(43) Pub. Date: Sep. 21, 2023

(54) EXPANSION CONTROL FOR BONDING

(71) Applicant: ADEIA SEMICONDUCTOR BONDING TECHNOLOGIES INC., San Jose, CA (US)

(72) Inventors: Jeremy Alfred Theil, Mountain View, CA (US); Thomas Workman, San Jose, CA (US); Cyprian Emeka Uzoh, San Jose, CA (US); Jesus Perez, Brownsboro, TX (US); Pawel Mrozek, San Jose, CA (US)

(21) Appl. No.: 18/183,828

(22) Filed: Mar. 14, 2023

Related U.S. Application Data
(60) Provisional application No. 63/320,525, filed on Mar. 16, 2022.

(51) Int. Cl. H01L 23/00

(52) U.S. Cl. CPC H01L 24/08; H01L 2224/0801; H01L 2224/08111; H01L 2224/08503

(57) ABSTRACT

An element and a bonded structure including the element are disclosed. The element can include a non-conductive region having a cavity extending at least partially through a thickness of the non-conductive region from the contact surface, and a contact feature formed in the cavity. The non-conductive region is configured to directly bond to a non-conductive region of a second element. The contact pad of the element is configured to directly bond to a contact pad of the second element. The contact pad can include a first conductive material and a second conductive material. The first conductive material can have a unit cell size greater than a unit cell size of the second conductive material. The first conductive material can be a metal alloying material. The first conductive material can be a metal silicide and the second conductive material can be a metal. A bonded conductive contact can include a conductive material and an alloying element, and an amount of the alloying element can vary through a thickness of the bonded conductive contact.

### RELATED APPLICATIONS

This application claims the priority benefit of U.S. Provisional Patent Application 63/320,525 filed on Mar. 16, 2022, entitled “EXPANSION CONTROL FOR BONDING,” which is incorporated by reference herein in its entirety.

### BACKGROUND

### Field

The field relates to a conductive feature with a controllable expansion rate.

### Description of the Related Art

Semiconductor elements, such as integrated device dies or chips, may be mounted or stacked on other elements. For example, a semiconductor element can be mounted to a carrier, such as a package substrate, an interposer, a reconstituted wafer or element, etc. As another example, a semiconductor element can be stacked on top of another semiconductor element, e.g., a first integrated device die can be stacked on a second integrated device die. Each of the semiconductor elements can have conductive pads for mechanically and electrically bonding the semiconductor elements to one another. There is a continuing need for improved methods for forming the conductive pads for reliable bonding.

### BRIEF DESCRIPTION OF THE DRAWINGS

The detailed description is set forth with reference to the accompanying figures. In the figures, the use of the same reference numbers in different figures indicates similar or identical items.

For this discussion, the devices and systems illustrated in the figures are shown as having a multiplicity of components. Various implementations of devices and/or systems, as described herein, may include fewer components and remain within the scope of the disclosure. Alternatively, other implementations of devices and/or systems may include additional components, or various combinations of the described components, and remain within the scope of the disclosure.

FIG. 1A is a schematic cross-sectional side view of a structure including two elements prior to annealing, accordingly an embodiment.

FIG. 1B is a schematic cross-sectional side view of a bonded structure after annealing, according to an embodiment.

FIGS. 2A-2E show schematic cross-sectional views of various steps in a process of forming a bonded structure of FIG. 1B according to an embodiment.

FIGS. 3 and 4 show material properties of various materials that can be used for the contact pad illustrated in FIGS. 1A and 1B.

FIG. 5 is a schematic cross-sectional side view of a structure, according to an embodiment.

FIG. 6 is a schematic cross-sectional side view of a bonded structure after annealing the structure of FIG. 5, according to an embodiment.

FIG. 7 shows material characteristics of various metals in combination with copper.

FIG. 8A is a schematic cross-sectional side view of an element according to an embodiment.

FIG. 8B is a schematic cross-sectional side view of the element after annealing the element of FIG. 8A.

FIGS. 9A-9F show schematic cross-sectional views of various steps in a process of forming a bonded structure according to an embodiment.

### DETAILED DESCRIPTION

The present disclosure describes methods of controlling metallic grain growth and expansion of conductive pads in elements, such as microelectronic elements. Various embodiments disclosed herein can be advantageous for direct metal bonding, such as direct hybrid bonding. For example, two or more semiconductor elements (such as integrated device dies, wafers, etc.) may be stacked on or bonded to one another to form a bonded structure. Conductive contact pads of one element may be electrically connected to corresponding conductive contact pads of another element. Any suitable number of elements can be stacked in the bonded structure. The methods and bond pad structures described herein can be useful in other contexts as well.

In some embodiments, the elements are directly bonded to one another without an adhesive. In various embodiments, a non-conductive (e.g., semiconductor or inorganic dielectric) material of a first element can be directly bonded to a corresponding non-conductive (e.g., semiconductor or inorganic dielectric) field region of a second element without an adhesive. In various embodiments, a conductive region (e.g., a metal pad) of the first element can be directly bonded to a corresponding conductive region (e.g., a metal pad) of the second element without an adhesive. The non-conductive material can be referred to as a nonconductive bonding region or bonding layer of the first element. In some embodiments, the non-conductive material of the first element can be directly bonded to the corresponding non-conductive material of the second element using bonding techniques without an adhesive using the direct bonding techniques disclosed at least in U.S. Pat. Nos. 9,564,414; 9,391,143; and 10,434,749, the entire contents of each of which are incorporated by reference herein in their entirety and for all purposes. In other applications, in a bonded structure, a non-conductive material of a first element can be directly bonded to a conductive material of a second element, such that a conductive material of the first element is intimately mated with a non-conductive material of the second element.

In various embodiments, direct bonds can be formed without an intervening adhesive. For example, semiconductor or dielectric bonding surfaces can be polished to a high degree of smoothness. The bonding surfaces can be cleaned and exposed to a plasma and/or etchants to activate the surfaces. In some embodiments, the surfaces can be terminated with a species after activation or during activation (e.g., during the plasma and/or etch processes). Without being limited by theory, in some embodiments, the activation process can be performed to break chemical bonds at the bonding surface, and the termination process can provide additional chemical species at the bonding surface that improves the bonding energy during direct bonding. In some embodiments, the activation and termination are provided in the same step, e.g., a plasma or wet etchant to activate and terminate the surfaces. In other embodiments, the bonding surface can be terminated in a separate treatment to provide the additional species for direct bonding. In various embodiments, the terminating species can comprise nitrogen. Further, in some embodiments, the bonding surfaces can be exposed to fluorine. For example, there may be one or multiple fluorine peaks near layer and/or bonding interfaces. Thus, in the directly bonded structures, the bonding interface between two non-conductive materials can comprise a very smooth interface with higher nitrogen content and/or fluorine peaks at the bonding interface. Additional examples of activation and/or termination treatments may be found throughout U.S. Pat. Nos. 9,564,414; 9,391,143; and 10,434,749, the entire contents of each of which are incorporated by reference herein in their entirety and for all purposes.

In various embodiments, conductive contact pads of the first element can also be directly bonded to corresponding conductive contact pads of the second element. For example, a direct hybrid bonding technique can be used to provide conductor-to-conductor direct bonds along a bond interface that includes covalently direct bonded dielectric-to-dielectric surfaces, prepared as described above. In various embodiments, the conductor-to-conductor (e.g., contact pad to contact pad) direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes. The bond structures described herein can also be useful for direct metal bonding without non-conductive region bonding, or for other bonding techniques.

In some embodiments, inorganic dielectric bonding surfaces can be prepared and directly bonded to one another without an intervening adhesive as explained above. Conductive contact pads (which may be surrounded by nonconductive dielectric field regions) may also directly bond to one another without an intervening adhesive. In some embodiments, the respective contact pads can be recessed below exterior (e.g., upper) surfaces of the dielectric field or nonconductive bonding regions, for example, recessed by less than 30 nm, less than 20 nm, less than 15 nm, or less than 10 nm, for example, recessed in a range of 2 nm to 20 nm, or in a range of 4 nm to 10 nm. The nonconductive bonding regions can be directly bonded to one another without an adhesive at room temperature in some embodiments and, subsequently, the bonded structure can be annealed. Upon annealing, the contact pads can expand with respect to the nonconductive bonding regions and contact one another to form a metal-to-metal direct bond. Beneficially, the use of hybrid bonding techniques, such as Direct Bond Interconnect, or DBI®, available commercially from Adeia of San Jose, CA, can enable high density of pads connected across the direct bond interface (e.g., small or fine pitches for regular arrays). In various embodiments, the contact pads can comprise copper, although other metals may be suitable.

Thus, in direct bonding processes, a first element can be directly bonded to a second element without an intervening adhesive. In some arrangements, the first element can comprise a singulated element, such as a singulated integrated device die. In other arrangements, the first element can comprise a carrier or substrate (e.g., a wafer) that includes a plurality (e.g., tens, hundreds, or more) of device regions that, when singulated, form a plurality of integrated device dies. Similarly, the second element can comprise a singulated element, such as a singulated integrated device die. In other arrangements, the second element can comprise a carrier or substrate (e.g., a wafer).

As explained herein, the first and second elements can be directly bonded to one another without an adhesive, which is different from a deposition process. The first and second elements can accordingly comprise non-deposited elements. Further, directly bonded structures, unlike deposited layers, can include a defect region along the bond interface in which nanovoids are present. The nanovoids may be formed due to activation of the bonding surfaces (e.g., exposure to a plasma). As explained above, the bond interface can include concentration of materials from the activation and/or last chemical treatment processes. For example, in embodiments that utilize a nitrogen plasma for activation, a nitrogen peak can be formed at the bond interface. In embodiments that utilize an oxygen plasma for activation, an oxygen peak can be formed at the bond interface. In some embodiments, the bond interface can comprise silicon oxynitride, silicon oxycarbonitride, or silicon carbonitride, with levels of nitrogen present at the bonding interface that are indicative of nitrogen termination of at least one of the elements prior to direct bonding. In some embodiments, nitrogen and nitrogen related moieties may not be present at the bonding interface. As explained herein, the direct bond can comprise a covalent bond, which is stronger than van Der Waals bonds. The bonding layers can also comprise polished surfaces that are planarized to a high degree of smoothness.

In various embodiments, the metal-to-metal bonds between the contact pads can be joined such that copper grains grow into each other across the bond interface. In some embodiments, the copper can have grains oriented vertically along the 111 crystal plane for improved copper diffusion across the bond interface. In some embodiments, the misorientation of 111 crystal plane in the conductive material may be in a range of ±30° with respect to the vertical direction from the surface of the conductive material. In some embodiments, the crystal misorientation can be in a range of ±20°, or in a range of ±15°, with respect to the vertical direction. The bond interface can extend substantially entirely to at least a portion of the bonded contact pads, such that there is substantially no gap between the nonconductive bonding regions at or near the bonded contact pads. In some embodiments, a barrier layer may be provided under the contact pads (e.g., which may include copper). In other embodiments, however, there may be no barrier layer under the contact pads, for example, as described in U.S. Pat. No. 11,195,748, which is incorporated by reference herein in its entirety and for all purposes.

Annealing temperatures and annealing durations for forming the metal-to-metal direct bond can affect the consumption of thermal budget by the annealing. It may be desirable to lower the annealing temperature and/or annealing duration to minimize consumption of the thermal (energy) budget. Surface diffusion of atoms along the 111 crystal plane (<111>) can be 3 to 4 orders of magnitude faster than along the 100 or 110 crystal planes. Also, a metal (e.g., Cu) with grains oriented along a 111 crystal plane can have a higher surface mobility as compared to conventional back end of line (BEOL) copper. Further, low-temperature direct metal-to-metal bonding is enabled by higher creep rate on the 111 plane of Cu and of reconstruction of the surface of the conductive pad. Therefore, it can be advantageous to have the 111 crystal plane on the bonding surface in order to shorten the annealing time and/or reduce the annealing temperature for direct bonding (e.g., direct hybrid bonding). The advantage to have the 111 crystal plane can be pronounced especially at lower temperatures because the metal surface diffusion (e.g., Cu surface diffusion) also slows down when the annealing temperature is reduced. Accordingly, in various embodiments disclosed herein, a crystal structure can have grains with 111 texture preferentially oriented vertically or parallel to the bonding surface to enhance metal diffusion (e.g., copper diffusion) during direct bonding. In some embodiments, the misorientation of 111 crystal plane in the conductive material may be in a range of ±30° with respect to the vertical direction from the surface of the conductive material. In some embodiments, the crystal misorientation can be in a range of ±20°, or in a range of ±15°, with respect to the vertical direction.

A metal layer can be formed with a process selected to plate a copper (Cu) layer having Cu in the 111 crystal orientation. The Cu layer may be deposited from a non-superfilling or super-filling electroplating bath, for example, with plating chemistry selected to optimize efficient filling of voids (e.g., vias, trenches) in the substrate, rather than to optimize the direct metal-to-metal bonding to occur during direct hybrid bonding. Subsequent metal treatment, described hereinbelow, can facilitate subsequent bonding such that any desirable plating chemistry can be employed to optimize for other considerations, such as filling noted above. The microstructure (e.g., a grain size) of the deposited or coated metal layer may be stabilized, for example by an annealing step, separate from the annealing step of the direct hybrid bonding that occurs later.

As described above, the contact pads can expand with respect to the nonconductive bonding regions and contact one another to form a metal-to-metal direct bond. Sufficient expansion during anneal can contribute to successful metal-to-metal bonding. For example, the expansion of the contact pads can be caused primarily by thermal expansion of a material (e.g., copper) of the contact pads relative to the nonconductive bonding regions. In some embodiments, by judiciously forming the contact pad with a material having an atomic unit cell comparatively larger than the unit cell of copper for example, the bonding temperature (e.g., annealing temperature) for bonding the contact pads can be lowered. A unit cell size increase of the contact pads can at least partially cause the contact pads to expand. The unit cell size can be referred to as a volume of the atomic unit cell of a material at room temperature at sea level or atmospheric pressure. The room temperature can be about 25° C., and the sea level or atmospheric pressure can be about 101325 Pa or 760 mm Hg. The unit cell is the smallest portion of a crystal lattice that shows the three-dimensional pattern of the entire crystal. For example, cobalt has a unit cell size of 10.913 Å³, titanium has a unit cell size of 34.714 Å³, nickel has a unit cell size of 10.722 Å³, and silicon has a unit cell size of 40.888 Å³, at room temperature at atmospheric pressure. Some contact pad materials can have lower thermal expansion rate than others, and some contact pad materials can be more costly than others or not suitable for direct bonding. Various embodiments disclosed herein uses two or more different types of conductive materials for forming the contact pads, thereby providing a sufficient direct bonding between contact pads at a relatively low material cost and relatively low thermal budget. For example, a contact pad can comprise two or more types of conductive materials that provide increased thermal expansion than one of the types of conductive materials to provide such sufficient direct bonding.

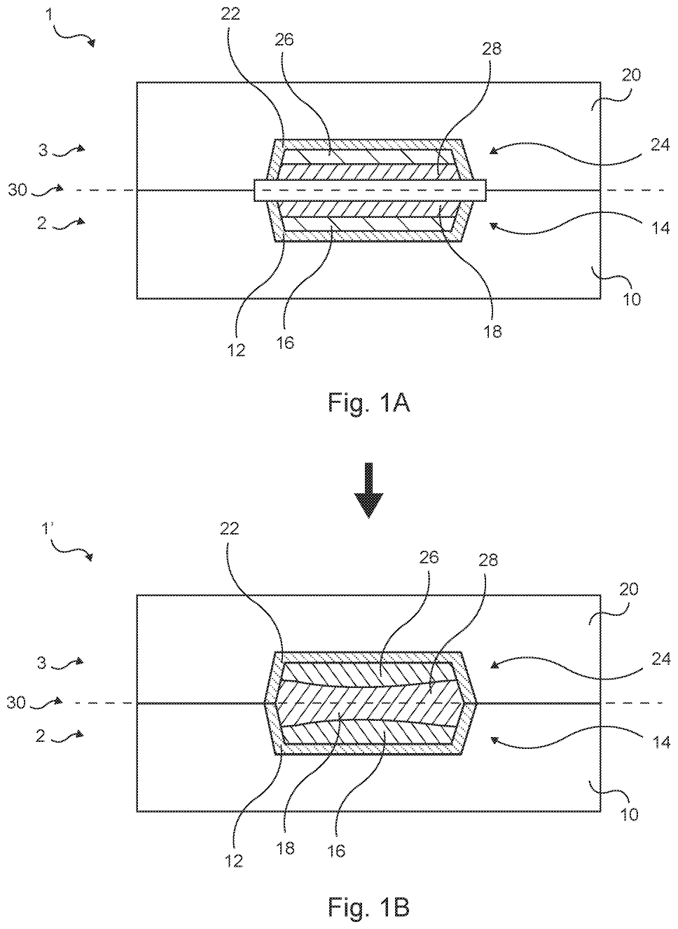

FIG. 1A is a schematic cross-sectional side view of a structure 1 including two elements (e.g., a first element 2 and a second element 3) prior to annealing, according to an embodiment. FIG. 1B is a schematic cross-sectional side view of a bonded structure 1′ (the structure 1 of FIG. 1A after annealing), according to an embodiment.

The first element 2 can comprise a non-conductive region 10 (e.g., a non-conductive or dielectric field region), a barrier layer 12, and a contact pad or conductive feature 14. The contact pad 14 can include a first conductive material 16 and a second conductive material 18. Similarly, the second element 3 can comprise a non-conductive region 20 (e.g., a non-conductive or dielectric field region), a barrier layer 22, and a contact pad or conductive feature 24. The contact pad 24 can include a first conductive material 26 and a second conductive material 28. The first element 2 and the second element 3 can be bonded to one another along a bonding interface 30. In some embodiments, the non-conductive region 10 and the non-conductive region 20 can be directly bonded to one another without an intervening adhesive. In some embodiments, the second conductive material 18 of the first element 2 and the second conductive material 28 of the second element 3 can be directly bonded to one another without an intervening adhesive. Though, in the illustrated embodiment, the structure 1 and the bonded structure 1′ includes identical elements 2, 3, the structure 1, 1′ can have different elements that are bonded together, in some embodiments.

The barrier layer 12 can be disposed between the non-conductive material 10 and the contact pad 14. In some embodiments, the barrier layer 12 can isolate the non-conductive material 10, 20 and the contact pad 14, 24 so as to prevent or mitigate diffusion of the conductive materials 16, 18, 26, 28 into the non-conductive materials 10, 20. In some embodiments, the barrier layer 12 can comprise a sputtered cobalt layer.

In some embodiments, a thermal expansion rate, a volumetric increase rate, and/or a unit cell size of the first conductive material 16 can be greater than a thermal expansion rate, a volumetric increase rate, and/or a unit cell size of the second conductive material 18. Certain material characteristics, such as the thermal expansion rate, the volumetric increase rate, and the unit cell size, of the first and second conductive materials 16, 18 may change depending on surrounding conditions. For example, the material characteristics of the first and second conductive materials 16, 18 may change depending on temperature or pressure. A skilled artisan will understand that when no condition is specified, the surrounding condition is at room temperature at sea level. When characteristics of two or more materials are compared herein, the characteristics of the materials in the same conditions are compared.

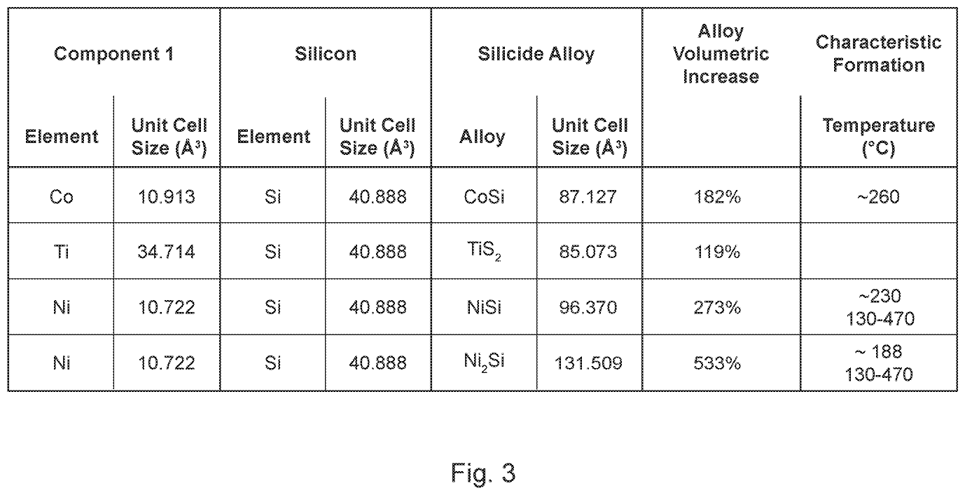

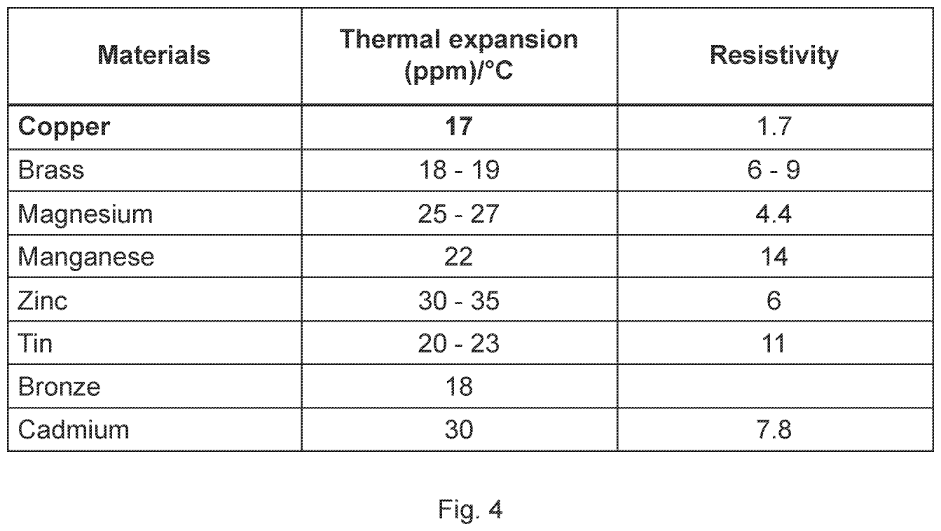

In some embodiments, the first conductive material 16 having a volumetric increase rate of at least 10% relative to a volumetric increase rate of the second conductive material 18, or a material of a back end of line (BEOL) layer (not shown) below the first and second conductive materials 16, 18. For example, the first conductive material 16 can have a volumetric increase rate in a range between 10% and 500%, between 10% to 275%, between 50% to 500%, or 50% to 275%, relative to a volumetric increase rate of the second conductive material 18, or a material of a back end of line (BEOL) layer (not shown) below the first and second conductive materials 16, 18. In some embodiments, the unit cell size of the first conductive material 16 can be at least 1.3 times greater than the unit cell size of the second conductive material 18. For example, the unit cell size of the first conductive material 16 can be at least 1.5, 2, 3, or 5 times greater than the unit cell size of the second conductive material 18. In some embodiments, the first conductive material 16 can comprise a metal silicide or an alloy forming metal. Some example materials for the first conductive material 16 can be found, for example, in FIGS. 3-4. In some embodiments, upon annealing at a particular temperature, the volumetric expansion of an alloy formed between the first conductive material 16 and the second conductive material 18 can be at least 10% higher than the volumetric expansion of the first conductive material 16 or the second conductive material 18. Additionally, further embodiments may have an element that comprises one or more BEOL layers. The BEOL layers can comprise metallization layers (conductive traces embedded in insulating layers) formed (e.g., deposited) over a back side of the barriers of the elements 1, 2. For example, the metallization layer can be formed directly over the back side of the barriers so as to contact the barriers. In some embodiments, the BEOL layers can include multiple layers and an uppermost layer of the BEOL layers can comprise a bonding layer. The volumetric expansion of the bonding layer (the conductive material 18, 28) of the first conductive feature or second conductive feature is at least 10% higher than the volumetric expansion of a the BEOL layers beneath the bonding layer. Selecting materials of the first and second conductive materials 16, 18 as disclosed herein can be critical in providing a sufficient direct bonding between contact pads 14, 24 at a relatively low material cost and relatively low thermal budget.

In some embodiments, the first conductive material 16 can be buried under (e.g., disposed at least partially under) the second conductive material 18. For example, the first conductive material 16 can be completely buried under the second conductive material 18. For example, as shown in FIG. 1B, the second conductive material 18 can be completely enclosed in a space between the barrier layer 12 and the overlying second conductive material 18. In some embodiments, the first conductive material 16 and the second conductive material 18 can combine with one another to form an alloy. The thermal expansion rate or the unit cell size of the formed alloy may be larger than the thermal expansion or unit cell size of precursor materials (the first conductive materials 16 or 18). In some other embodiments, the first conductive material 16 and the second conductive material 18 may not combine with each other.

In some embodiments, the first conductive material 16 can be exposed on a contact surface of the contact pad 14. In some embodiments, it may be beneficial to select a material of the second conductive material 18, 28 that is compatible with a chemical-mechanical polishing (CMP) process in preparation for direct bonding. A material that has a hardness that does not cause excessive smearing or dishing during the polishing process can be a CMP compatible material. Because the first conductive material 16, 26 is embedded below the second conductive material 18, 28, the first conductive material 16, 26 may or may not be compatible with a CMP process.

A thickness of the first conductive material 16 can be thinner than a thickness of the second conductive material 18. The thickness of the first conductive material 16, 26 can be determined at least in part by the expansion rate of the material of the first conductive material 16, 26, and a gap between the contact pads 14, 24 prior to annealing. In some embodiments, depending on the depth of the cavity, the thickness of the first conductive material 16, 26 can be in a range of, for example, 20 nm to 20000 nm, 30 nm to 17500 nm, 40 nm to 15000 nm, 50 nm to 10000 nm, 50 nm to 7000 nm, or 50 nm to 500 nm. Selecting the thickness of the first conductive material 16, 26 from these ranges can contribute to providing a sufficient direct bonding between contact pads 14, 24 at a relatively low material cost and relatively low thermal budget.

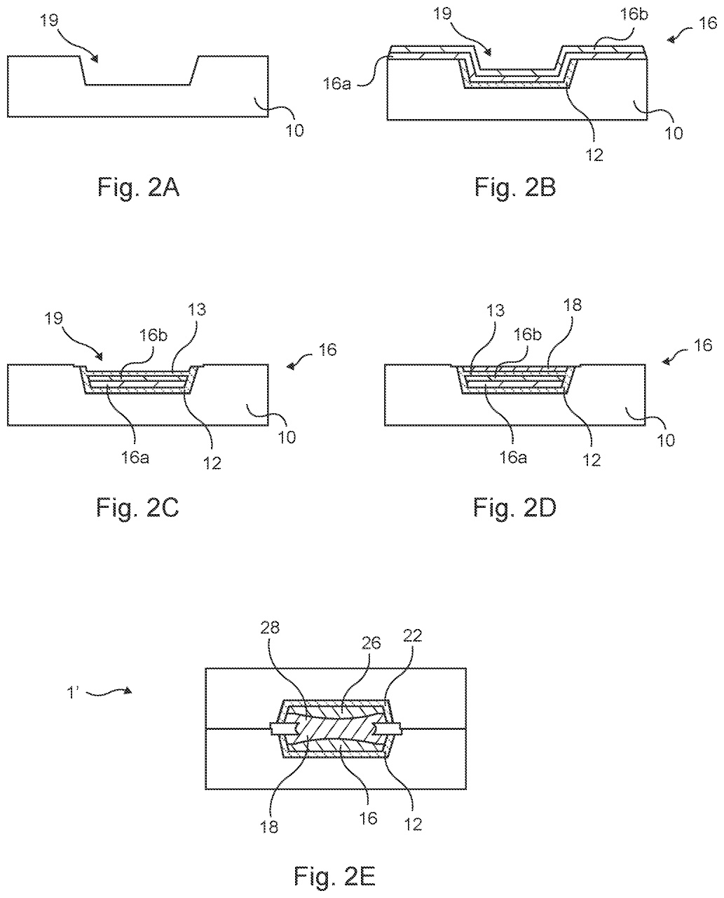

FIGS. 2A-2E show schematic cross-sectional views of various steps in a process of forming a bonded structure 1′ according to an embodiment. At FIG. 2A, a cavity 19 can be formed in a non-conductive material 10. In some embodiments, the cavity 19 can be formed by way of selective etching of the non-conductive material 10. At FIG. 2B, a barrier 12 layer and a first conductive material 16 can be provided in the cavity 19. The first conductive material 16 can comprise a plurality of constituent elements 16a, 16b. For example, the barrier layer 12 and the first conductive material 16 can be provided by way of atomic layer deposition (ALD), sputtering and plating or combinations thereof. The plating step may comprise electroless or electrolytic deposition. At least a portion of the first conductive material 16 can be removed by way of, for example, an etching (e.g., dry or wet etching) process and/or a photolithography process. At FIG. 2C, in some embodiments, a second barrier layer 13 can be provided in the cavity over the first conductive material 16. In some embodiments, the first conductive material 16 can be enclosed between the first and second barrier layers 12, 13. In other embodiments, no second barrier 13 may be provided (see FIG. 1A). At FIG. 2D, a second conductive material 18 can be provided. A surface of the non-conductive material 10 and/or a surface of the second conductive material 18 can be polished, by way of, for example, CMP, to prepare the element for direct bonding to another element. In some embodiments, after polishing the surface of the non-conductive material 10 and/or the surface of the second conductive material 18, the surface of the second conductive material 18 can be recessed relative to the surface of the non-conductive material 10. At FIG. 2E, the element can be directly bonded (e.g., directly hybrid bonded) to another element. The elements can be directly bonded after cleaning and activating the bonding surface of one or both of the elements by known methods. For example, the activation process may comprise cleaning at least one of the bonding surfaces of the elements to remove unwanted particulates, and/or exposing the bonding surface to one or more plasma processing, rinsing and drying the bonding surface. A rinsing solvent for the rinsing may comprise deionized (DI) water or low molecular weight alcohols. The non-conductive material of the element can be directly bonded to a non-conductive material of the other element. After bonding the non-conductive materials of the two elements, the structure can be annealed at a higher temperature to bond the second conductive material to a contact pad of the other element. In some embodiments, the first conductive material 16 can form an alloy, for example with the first and/or second barrier layers 12, 13, that has a unit cell size greater than a unit cell size of the second conductive material 18. For example, the alloy can comprise copper-zinc alloy, magnesium alloy, or cobalt silicide alloy.

FIGS. 3 and 4 show material properties of various materials that can be used for the contact pad 14, 24 illustrated in FIGS. 1A and 1B. An alloy volumetric increase shown in FIG. 3 is an alloy volumetric increase rate of each of the silicide alloys listed in FIG. 3 as compared to copper. The silicide alloys listed in FIG. 3 can be examples of the first conductive material 16, 26. The materials listed in FIG. 4 can be examples of the first conductive material 16, 26. In some embodiments, brass, bronze, or cadmium copper alloy can be electroplated from an alkaline bath comprising suitable complexing agent into damascene cavity. As shown in FIG. 3, the first conductive material 16, 26 can comprise copper, titanium, nickel, brass, magnesium, manganese, zinc, tin, bronze, or cadmium. Beneficially, the incorporation of the embedded first conductive material 16, 26 can reduce the annealing temperature sufficient to cause metal expansion and direct electrical contact between opposing pads (e.g., between opposing second conductive materials 18, 28). The increased expansion characteristics of the first conductive material 16, 26 as compared to the second conductive materials 18, 28 can facilitate improved direct bond yield at lower temperatures, while also providing a surface of the second conductive material 18, 28 that is compatible with CMP for preparation for direct bonding.

In some embodiments in which the first conductive material 16, 26 comprises nickel (Ni) and the second conductive material 18, 28 comprises silicon (Si), a nickel silicide (Ni₂Si) layer can be formed. For an element with a thickness of 2 μm and a contact recess of 20 nm prior to bonding, a thickness of the nickel silicide layer can be 27 nm or greater based on 533% volumetric expansion of nickel silicide to compensate for the recess without a coefficient of thermal expansion (CTE) expansion. The relationship between a change in recess (ΔL), a volumetric expansion (V1), and a layer thickness (L1) can be expressed by the following equation (Equation 1) and are shown in the following table (Table 1).

ΔL=(∛V̅1̅)*L1 (Equation 1)

TABLE 1

| Material | V1 | L1 | ΔL |
|---|---|---|---|
| Ni2Si | 533% | 27 nm | 20 nm |

In some embodiments, the first conductive material 16, 26 can comprise copper (Cu) and the second conductive material 18, 28 can comprise magnesium (Mg). Including the combination of copper and magnesium in a contact pad can enable lowering the annealing temperature for bonding the contact pad to a corresponding pad of another element as compared to including only copper in the contact pad. For example, the annealing temperature can be lowered by about 125° C. under some conditions. The following table (Table 2) shows a comparison between some parameters of a copper pad (both the first and second conductive materials comprise copper) and a multi-layer pad that includes 50% copper and 50% magnesium (the first conductive material comprises magnesium and the second conductive material comprises copper).

TABLE 2

| | | |
|---|---|---|
| Parameter | Cu | Cu + Mg |

| | | |
|---|---|---|
| α_{Cu} | 17 | 17 |
| α₁ | 17 (Cu) | 26 (Mg) |

| | | | | |
|---|---|---|---|---|
| L_{Cu} | 1 | um | 1 | um |
| L₁ | 1 | um | 1 | um |
| ΔT | 600 | C. | 475 | C. |
| ΔL | 20 | nm | 20 | nm |

In Table 2, α_{Cu} represents the CTE of copper, α₁ represents the CTE of the first conductive material, L_{Cu} represents the thickness of the copper layer (the second conductive material), L₁ represents the thickness of the second conductive material, ΔT represents the change in temperature relative to an original temperature of 25° C., and ΔL represents the change in recess before and after annealing. The relationship between these parameters can be expressed by the following equation (Equation 2):

ΔL=(α_{Cu}L_{Cu}+α₁L₁)ΔT (Equation 2.

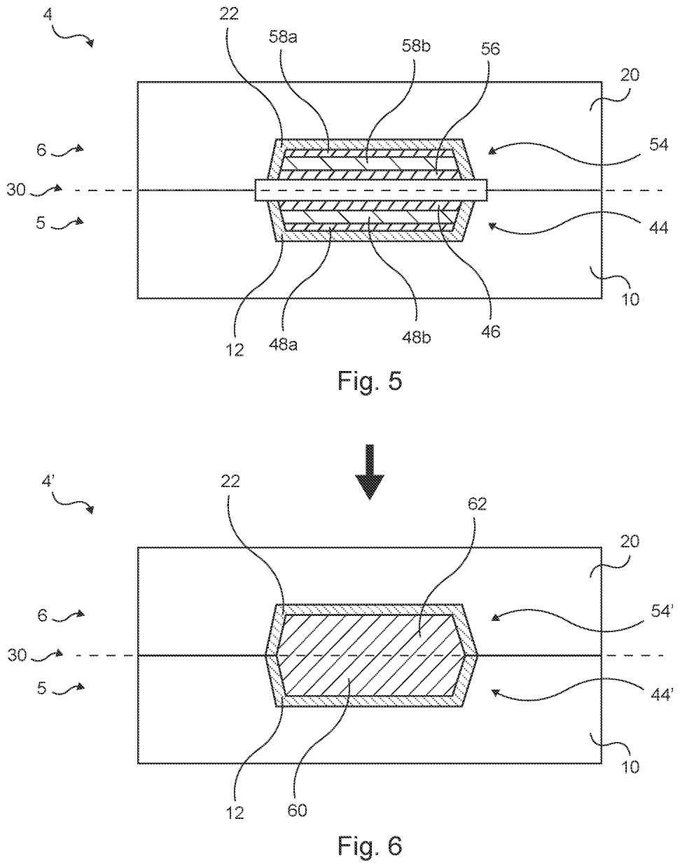

FIG. 5 is a schematic cross-sectional side view of a structure 4 including a first element 5 and a second element 6 prior to annealing, according to an embodiment. FIG. 6 is a schematic cross-sectional side view of a bonded structure 4′ (after annealing the structure 4 of FIG. 5), according to an embodiment. Unless otherwise noted, the components shown in FIGS. 5 and 6 can be the same or generally similar to the like components of FIGS. 1A and 1B.

The first element 5 can comprise a non-conductive region 10, a barrier layer 12, and a contact pad or conductive feature 44. The contact pad 44 can include a first conductive material 46, a first layer 48a of a second conductive material and a second layer 48b of the second conductive material. In some embodiments, the first conductive material 46 can be vertically sandwiched between the first layer 48a and the second layer 48b. Similarly, the second element 6 can comprise a non-conductive region 20, a barrier layer 22, and a contact pad or conductive feature 54. The contact pad 54 can include a first conductive material 56, a first layer 58a of a second conductive material and a second layer 58b of the second conductive material. The first element 5 and the second element 6 can be bonded (e.g., directly hybrid bonded) to one another along a bonding interface 30. In some embodiments, the non-conductive region 10 and the non-conductive region 20 can be directly bonded to one another without an intervening adhesive. In various embodiments, the first conductive material 46, 56 can comprise an alloying element (e.g., an alloying metal) that, when annealed, forms a metal alloy with the second conductive material. For example, the first conductive material 46, 56 can comprise zinc (Zn), beryllium (Be), palladium (Pd), aluminum (Al), or the like materials. The annealing process can form the contact pads 44, 54 into a different form thereby defining contact pads 44′, 54′. For example, the first conductive material 46, 56, a first layer 48a, 58a, and a second layer 48b, 58b can at least partially form an alloy 60, 62. After annealing the structure 4 of FIG. 5, the contact pad 44′ and the contact pad 54′ can expand so as to contact one another and also forms a metallic alloy. When the alloy 60, 62 is formed prior to the annealing for bonding the contact pad 44′ and the contact pad 54′, the alloy 60, 62 can be compatible with a CMP process for preparation for direct bonding. In some embodiments, the contact pad 44′ and the contact pad 54′ can be directly bonded to one another without an intervening adhesive. In some embodiments, the contact pad 44′ and the contact pad 54′ can comprise a gradient of the alloying element (e.g., a gradient of the first conductive material 46, 56). In the illustrated embodiment, the structure 4 and the bonded structure 4′ includes identical elements 5, 6, but in other embodiments a structure 4 can have different elements that are bonded together. In some embodiments, the resistivity of the alloy 60, 62 formed by bonding the elements 5 and 6 can be less than 20, less than 15, less than 10, or less than 5 times higher than the resistivity of a material of a BEOL layer below the bonding layer. For example, the alloy 60, 62 can include a lower resistivity metal (e.g., nickel) and the material of the BEOL layer can include a higher resistivity metal (e.g., copper).

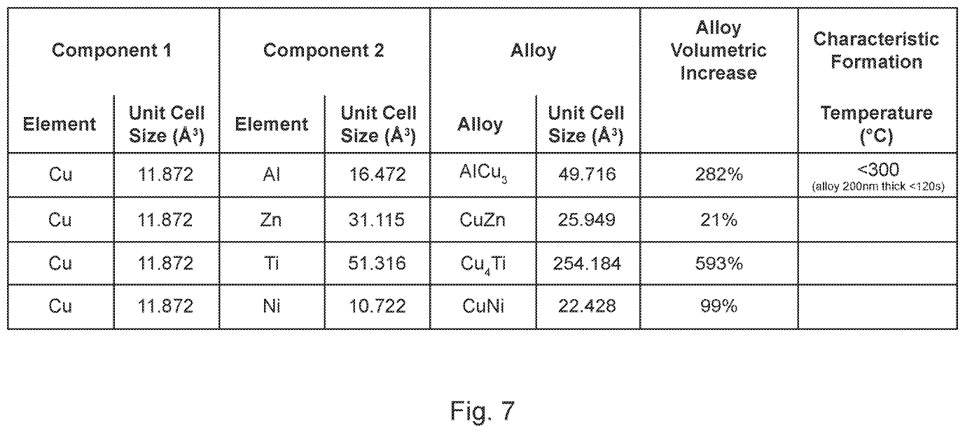

FIG. 7 shows example materials of the first conductive element. FIG. 7 also shows material characteristics of various metals in combination with copper. A volumetric expansion of a pad can be calculated by the following equation (Equation 3):

$$Volumetric Expansion = \frac{UCalloy - ( xUCc 1 + yUCc 2 )}{xUCc 1 + yUCc 2} . \qquad ( Equation 3 )$$

For example, when copper-zinc alloy (Cu₃Zn) is applied to Equation 3, it can be expressed as follow:

$$Volumetric Expansion ( {Cu}_{3} Zn ) = \frac{UCalloy - ( \frac{3}{4} UCCu + \frac{1}{4} UCZn )}{\frac{3}{4} UCCu + \frac{1}{4} UCZn} . \qquad ( Equation 4 )$$

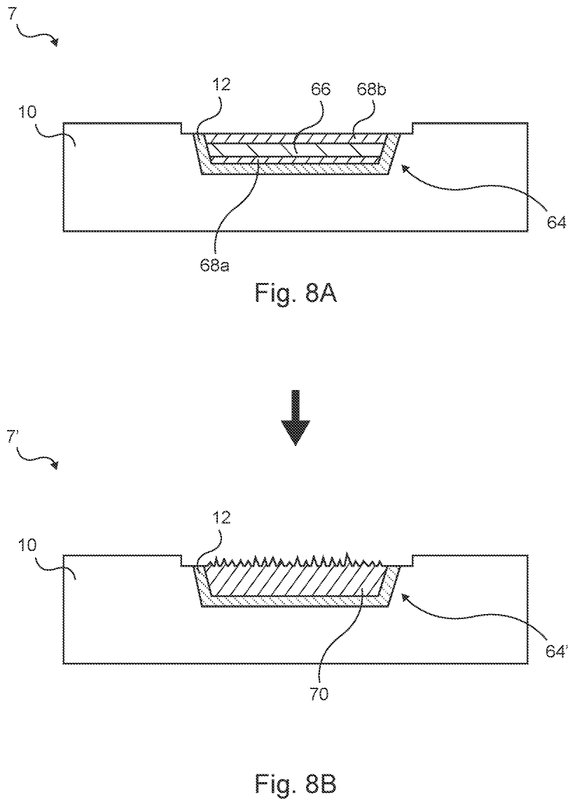

FIG. 8A is a schematic cross-sectional side view of an element 7 according to an embodiment. FIG. 8B is a schematic cross-sectional side view of the element 7′ after annealing the element 7 of FIG. 8A. Unless otherwise noted, the components shown in FIGS. 8A and 6 can be the same or generally similar to the like components of FIGS. 1A, 1B, 5, and 6.

The element 7 can comprise a non-conductive region 10, a barrier layer 12, and a contact pad or conductive feature 64. The contact pad 64 can include a first conductive material 66, a first layer 68a of a second conductive material and a second layer 68b of the second conductive material. In some embodiments, the second layer 68b may be omitted. The first conductive material 66 and the second conductive material (the first layer 68a and the second layer 68b) can be selected so as to increase roughness of a surface of an alloyed conductive feature 70 during annealing. The first conductive material 66 can be positioned at or near a contact surface of the contact pad 64. In some embodiments, the first conductive material 66 can be positioned within 25% of a thickness of the contact pad 64 from its contact surface.

In some embodiments, the first conductive material 66 can comprise an alloying material. In some embodiments, the first conductive material 66 can comprise a hexagonal crystal structure, and the second conductive material (the first layer 68a and the second layer 68b) can comprise a face centered cubic structure. For example, the first conductive material 66 can comprise titanium, and the second conductive material (the first layer 68a and the second layer 68b) can comprise copper. After annealing the element 7, the contact pad 64 can form an orthorhombic crystal structure. When the orthorhombic crystal structure is formed, a surface roughness of the contact pad 64 can increase. The contact pad 64′ can comprise spikes or whiskers as a result of the formation of the orthorhombic crystal structure. The surface roughness of the surface of the alloyed conductive feature 70 of element 7 may be in a range between 3 nm and 100 nm, or between 3 nm and 50 nm. The surface roughness of the alloyed conductive feature 70 can be higher than a roughness of a bonding surface of the non-conductive region which can be less than 1 nm and preferably less than 0.5 nm. Bonding the alloyed conductive feature 70 that has a relatively rough surface morphologies at elevated temperature induces a corresponding conductive feature to bridge the recess between the conductive features more efficiently. The bridging of the recess initiates physical contact between the metal conductive features on opposing elements (at lower temperatures) to promote a metallurgical bond at lower temperatures.

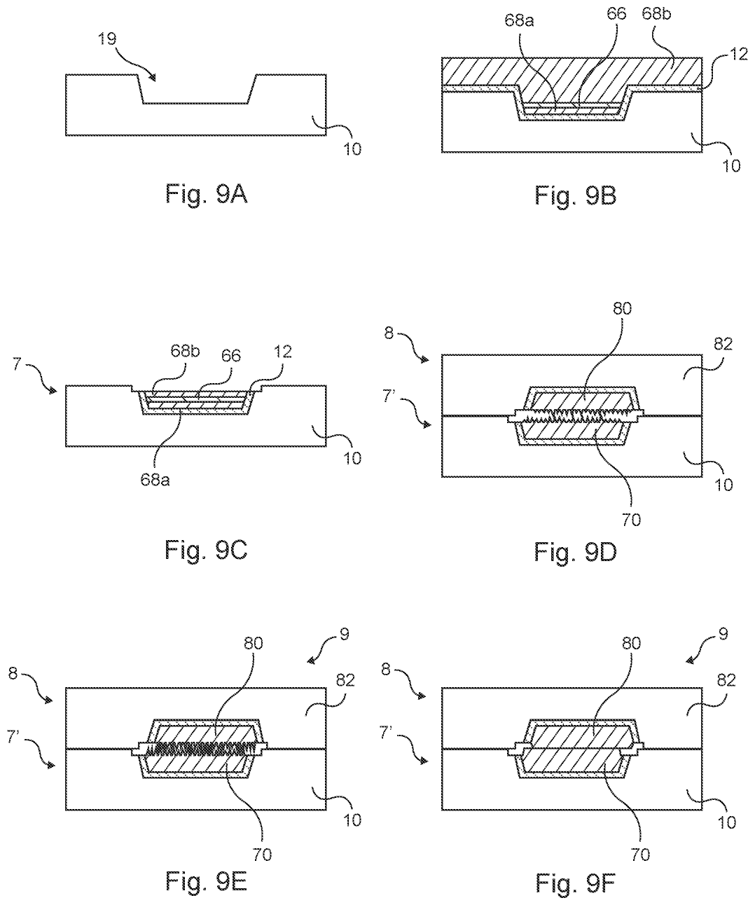

FIGS. 9A-9F show schematic cross-sectional views of various steps in a process of forming a bonded structure 9 according to an embodiment. At FIG. 9A, a cavity 19 can be formed in a non-conductive material 10. In some embodiments, the cavity 19 can be formed by way of selective etching. At FIG. 9B, a barrier layer 12, a first conductive material 66, and a second conductive material (e.g., first and second layers 68a, 68b) can be provided in the cavity 19 and at least partially over a surface of the non-conductive material 10. For example, the first conductive material 66, and the second conductive material (the first and second layers 68a, 68b) can be provided by way of sputtering, plating or combinations of each. At FIG. 9C, a surface of the non-conductive material 10 and/or the second layer 68b of the second conductive material can be polished, by way of, for example, CMP, to define an element (e.g., a first element 7). In some embodiments, the second layer 68b can be recessed relative to the surface of the non-conductive material 10. At FIG. 9D, the element (the first element 7) can be bonded to another element (a second element 8) after fully preparing at least one of the surfaces of the first and second elements 7, 8 for bonding (e.g., direct hybrid bonding). The non-conductive material 10 of the first element 7′ can be directly bonded to a non-conductive material 82 of the second element 8. After bonding the non-conductive materials 10, 82 of the two elements 7, 8, the structure can be annealed to bond the second conductive material 68b to a contact pad 80 of the second element 8. During the bonding process, the first conductive material 66, and the second conductive material (the first and second layers 68a, 68b) can at least partially form an alloy to define the alloyed conductive feature 70. At FIG. 9D, nanoscale roughened surface, spikes, protrusions, or whiskers can be formed on contact surfaces of the alloyed conductive feature 70 and/or the contact pad 80 of the elements 7, 8. The nanoscale roughened bonding surface of the conductive material of first element 7 or second element 8 can be formed by a judicious selection of materials that have different crystal lattice symmetries for the first material 66 and the second material (the first layer and second layer 68a, 68b) as described above. Other known methods, for example, applying dry or wet etchants to selectively, very slightly etch away a portion of the grain boundaries of the conductive material of first element 7 or second element 8. FIG. 9E shows the bonded structure 9 of FIG. 9D after a first period of time after bonding the first and second elements 7, 8 at an elevated temperature. The contact pads of the elements 7, 8, can diffuse to one another over time. At the first period of time, the nanoscale roughened surface, spikes, protrusions, or whiskers may be observed in some embodiments. FIG. 9F shows the bonded structure 9 of FIG. 9E after a second period of time after bonding the first and second elements 7, 8. The second period of time is greater than the first period of time. After the second period of time, the nanoscale roughened surface, spikes, protrusions, or whiskers may not be visible in some embodiments. In some other embodiments, after the second period of time, the nanoscale roughened surface, spikes, protrusions, or whiskers may be observed.

In some embodiments, a bonded structure disclosed herein can comprise a void between a contact pad of one element and a contact pad of another element. A gas in the void can expand to push a material of the contact pads to an interior surface.

In one aspect, an element having a contact surface is disclosed. The element can include a non-conductive region having a cavity extending at least partially through a thickness of the non-conductive region from the contact surface, and a contact pad formed in the cavity. The contact pad includes a first conductive material and a second conductive material. The first conductive material has a unit cell size greater than a unit cell size of the second conductive material. The first conductive material is a metal alloying material. The non-conductive region is configured to directly bond to a non-conductive region of a second element, and the contact pad of the element is configured to directly bond to a contact pad of the second element.

In one embodiment, the unit cell size of the first conductive material is at least 1.3 times greater than the unit cell size of the second conductive material.

In one embodiment, the element further includes a barrier layer conformally disposed along surfaces of the cavity.

In one embodiment, the first conductive material is disposed between a bottom surface of the cavity and the second conductive material.

In one embodiment, the first conductive material is completely buried under the second conductive material.

In one embodiment, the first conductive material is not exposed.

In one embodiment, the second conductive material is copper.

In one embodiment, the first conductive material has a characteristic formation temperature of less than 230° C. The first conductive material can have a characteristic formation temperature of less than 130° C.

In one embodiment, the first conductive material is a metal silicide. The metal silicide can include nickel, titanium, or cobalt.

In one embodiment, the first conductive material includes zinc, titanium, or nickel.

In one embodiment, the second conductive material includes a face centered cubic structure, and the first conductive material includes a hexagonal crystal structure. The second conductive material can include copper, and the first conductive material can include titanium. A resistivity of the first conductive material can be greater than a resistivity of the second conductive material. The resistivity of the first conductive material can be less than 40 times the resistivity of the second conductive material. The resistivity of the first conductive material can be less than 20 times the resistivity of the second conductive material. A thickness of the second conductive material can be greater than a thickness of the first conductive material.

In one embodiment, first conductive material is a chemical-mechanical polishing compatible material.

In one aspect, a first element having a contact surface is disclosed. The first element can include a non-conductive region having a cavity extending at least partially through a thickness of the non-conductive region from the contact surface, and a contact pad formed in the cavity. The contact pad includes a metal and a metal silicide. The metal silicide has a unit cell size greater than a unit cell size of the metal. The non-conductive region is configured to directly bond to a non-conductive region of a second element, and the metal is configured to directly bond to a contact pad of the second element.

In one embodiment, the first element further includes a barrier layer conformally disposed along surfaces of the cavity.

In one embodiment, the metal silicide is disposed between a bottom surface of the cavity and the metal.

In one embodiment, the metal silicide is completely buried under the metal.

In one embodiment, the metal is not exposed.

In one embodiment, the metal is copper.

In one embodiment, the metal silicide is a metal alloying material.

In one embodiment, the metal silicide has a characteristic formation temperature of less than 230° C.

In one embodiment, the metal silicide includes nickel, titanium, or copper.

In one embodiment, a resistivity of the metal silicide is greater than a resistivity of the metal. The resistivity of the metal silicide can be less than 40 times the resistivity of the metal. The resistivity of the metal silicide can be less than 20 times the resistivity of the metal.

In one embodiment, a thickness of the metal is greater than a thickness of the metal silicide.

In one embodiment, the metal and the metal silicide do not react with one another.

In one embodiment, the metal includes copper and the metal silicide includes zinc.

In one embodiment, the metal silicide is a chemical-mechanical polishing compatible material.

In one aspect, a bonded structure is disclosed. The bonded structure can include a first element having a first non-conductive region and a first conductive feature, and a second element having a second non-conductive region directly bonded to the first non-conductive region, and a second conductive feature directly bonded to the first conductive feature to define a bonded conductive contact. The bonded conductive contact includes a first conductive material and a second conductive material. The first conductive material has a unit cell size greater than a unit cell size of the second conductive material. The first conductive material is an alloy comprising the second conductive material.

In one embodiment, the bonded conductive contact includes a gradient of alloying element.

In one aspect, a bonded structure is disclosed. The bonded structure can include a first element having a first non-conductive region and a first conductive feature, and a second element having a second non-conductive region directly bonded to the first non-conductive region, and a second conductive feature directly bonded to the first conductive feature to define a bonded conductive contact. The bonded conductive contact includes a first conductive material and a second conductive material. The first conductive material has a unit cell size greater than a unit cell size of the second conductive material. The first conductive feature includes a metal silicide.

In one embodiment, the first element further includes a barrier layer between the first non-conductive region and the first conductive feature.

In one embodiment, the metal silicide includes nickel, titanium, or copper.

In one aspect, a bonded structure is disclosed. The bonded structure can include a first element having a first non-conductive region and a first conductive feature, and a second element having a second non-conductive region directly bonded to the first non-conductive region, and a second conductive feature directly bonded to the first conductive feature to define a bonded conductive contact. The bonded conductive contact includes a conductive material and an alloying element. An amount of the alloying element varies through a thickness of the bonded conductive contact.

In one embodiment, the first element further includes a barrier layer between the first non-conductive region and the first conductive feature.

In one embodiment, the first conductive feature includes a metal silicide. The metal silicide can include nickel, titanium, or copper.

In one embodiment, the bonded conductive contact includes an orthorhombic crystal structure.

In one embodiment, the bonded conductive contact has a unit cell size that is greater than a unit cell size of the conductive material.

In one aspect, a bonded structure is disclosed. The bonded structure can include a first element having a first non-conductive region and a first conductive feature, and a second element having a second non-conductive region directly bonded to the first non-conductive region, and a second conductive feature directly bonded to the first conductive feature to define a bonded conductive contact. The bonded conductive contact includes a lower symmetry crystal structure than the first conductive feature.

In one embodiment, the bonded conductive contact includes an orthorhombic or hexagonal crystal structure.

In one embodiment, the bonded conductive contact includes a gradient of alloying element.

In one embodiment, the first element further includes a barrier layer between the first non-conductive region and the first conductive feature.

In one embodiment, the bonded conductive contact includes copper titanium.

In one aspect, a bonded structure is disclosed. The bonded structure can include a first element having a first contact surface. The first element includes a first non-conductive region having a first cavity extending at least partially through a thickness of the non-conductive region from the first contact surface, and a first contact pad formed in the first cavity. The contact pad includes a first conductive material and a second conductive material. The first conductive material has a unit cell size greater than a unit cell size of the second conductive material. The first conductive material is a metal alloying material. The bonded structure can include a second element having a second contact surface directly bonded to the first contact surface. The second element includes a second non-conductive region directly bonded to the first non-conductive region, and a second contact pad directly bonded to the first contact pad.

In one embodiment, the bonded structure further includes a barrier layer conformally disposed along surfaces of the first cavity.

In one embodiment, the first conductive material is disposed between a bottom surface of the first cavity and the second conductive material. The first conductive material can be completely buried under the second conductive material. The directly bonded first and second contact pads can define a bonded conductive contact that includes an orthorhombic crystal structure. The directly bonded contact pads can include copper titanium.

In one embodiment, the directly bonded first and second contact pads define a bonded conductive contact that includes a gradient of alloying element.

In one aspect, a method of forming an element is disclosed. The method can include forming a cavity in a non-conductive material, providing a first conductive material having a first unit cell size in the cavity, providing a second conductive material having a second unit cell size in the cavity over the first conductive material, and polishing a surface of the non-conductive material and a surface of the second conductive material. The first unit cell size is greater than the second unit cell size.

In one embodiment, the forming the cavity includes etching a portion of the non-conductive material.

In one embodiment, the method further includes providing a barrier layer conformally along surfaces of the cavity.

In one embodiment, the providing the first conductive material includes plating the first conductive material.

In one embodiment, the second conductive material is copper.

In one embodiment, the first conductive material is a metal alloying material.

In one embodiment, the first conductive material has a characteristic formation temperature of less than 230° C.

In one embodiment, the first conductive material is a metal silicide. The metal silicide can include nickel, titanium, or copper.

In one embodiment, the first conductive material includes aluminum, zinc, titanium, or nickel.

In one embodiment, the second conductive material includes a face centered cubic structure, and the first conductive material includes a hexagonal crystal structure.

In one embodiment, the second conductive material includes copper, and the first conductive material includes titanium.

In one embodiment, a resistivity of the first conductive material is greater than a resistivity of the second conductive material. The resistivity of the first conductive material can be less than 40 times the resistivity of the second conductive material. The resistivity of the first conductive material can be less than 20 times the resistivity of the second conductive material.

In one embodiment, a thickness of the second conductive material is greater than a thickness of the first conductive material.

In one embodiment, the polishing includes polishing the surface of the non-conductive material and the surface of the second conductive material by way of a chemical-mechanical polishing compatible material.

In one embodiment, the element is formed without annealing. A method of forming a bonded structure including the element and a second element having a contact pad can include annealing the first conductive material, the second conductive material, and the contact pad thereby expanding the first conductive material, the second conductive material, and the contact pad to form a bonded conductive contact. The annealing can form an alloy between the first and second materials.

In one aspect, a method of forming an element is disclosed. The method can include forming a cavity in a non-conductive material, providing a first barrier layer in the cavity, providing a first conductive material having a first unit cell size in the cavity over the first barrier layer, providing a second barrier layer in the cavity over the first conductive material, providing a second conductive material having a second unit cell size in the cavity over the second barrier layer, polishing a surface of the non-conductive material and a surface of the second conductive material. The first unit cell size is greater than the second unit cell size.

In one embodiment, the forming the cavity includes etching a portion of the non-conductive material.

In one embodiment, the providing the first conductive material includes plating the first conductive material.

In one embodiment, the second conductive material is copper.

In one embodiment, the first conductive material is a metal alloying material.

In one embodiment, the first conductive material having a characteristic formation temperature of less than 230° C.

In one embodiment, the first conductive material is a metal silicide.

In one embodiment, the second conductive material includes a face centered cubic structure, and the first conductive material includes a hexagonal crystal structure. The second conductive material can include copper, and the first conductive material can include titanium.

In one embodiment, a resistivity of the first conductive material is greater than a resistivity of the second conductive material. The resistivity of the first conductive material can be less than 40 times the resistivity of the second conductive material. The resistivity of the second conductive material can be less than 20 times the resistivity of the first conductive material.

In one embodiment, a thickness of the second conductive material is greater than a thickness of the first conductive material.

In one embodiment, the polishing includes polishing the surface of the non-conductive material and the surface of the second conductive material by way of a chemical-mechanical polishing compatible material.

In one embodiment, the element is formed without annealing.

In one aspect, a method of forming an element is disclosed. The method can include forming a cavity in a non-conductive material, providing a first conductive material having a hexagonal crystal structure, providing a second conductive material having a face centered cubic structure, and polishing a surface of the non-conductive material and a surface of the first conductive material.

In one embodiment, the forming the cavity includes etching a portion of the non-conductive material.

In one embodiment, the providing the first conductive material includes plating the first conductive material.

In one embodiment, the second conductive material is copper.

In one embodiment, the first conductive material has a characteristic formation temperature of less than 230° C.

In one embodiment, the second conductive material includes copper, and the first conductive material includes titanium.

In one embodiment, a resistivity of the first conductive material is greater than a resistivity of the second conductive material.

In one embodiment, a thickness of the second conductive material is greater than a thickness of the first conductive material.

In one embodiment, the polishing includes polishing the surface of the non-conductive material and the surface of the second conductive material by way of a chemical-mechanical polishing compatible material.

In one embodiment, the element is formed without annealing. A method of forming a bonded structure including the element and a second element having a contact pad can include annealing the first conductive material, the second conductive material, and the contact pad thereby expanding the first conductive material, the second conductive material, and the contact pad to form a bonded conductive contact. The annealing can form an alloy between the first and second conductive materials.

In one aspect, a method of forming a bonded structure is disclosed. The method can include providing a first element having a first non-conductive region and a first conductive feature. The first conductive feature includes a first conductive material and a second conductive material. The first conductive material has a unit cell size greater than a unit cell size of the second conductive material. The first conductive material is a metal alloying material. The method can include providing a second element having a second non-conductive region and a second conductive feature. The method can include directly bonding the first non-conductive region and the second non-conductive region, and annealing the first conductive feature and the second conductive feature thereby bonding the first conductive material of the first conductive feature and the second conductive feature.

In one embodiment, the providing the first element includes forming a cavity in the first non-conductive region and at least partially filling the cavity with the first conductive feature. The forming the cavity can include etching a portion of the non-conductive material. The method can further include providing a barrier layer conformally along surfaces of the cavity. The providing the first conductive feature can include plating the first conductive feature.

In one embodiment, the first conductive material is copper.

In one embodiment, the second conductive material has a characteristic formation temperature of less than 230° C.

In one embodiment, the second conductive material is a metal silicide.

The metal silicide can include nickel, titanium, or copper.

In one embodiment, the second conductive material includes aluminum, zinc, titanium, or nickel.

In one embodiment, the first conductive material includes a face centered cubic structure, and the second conductive material includes a hexagonal crystal structure. The first conductive material can include copper, and the second conductive material can include titanium.

In one embodiment, a resistivity of the second conductive material is greater than a resistivity of the first conductive material. The resistivity of the second conductive material can be less than 40 times the resistivity of the first conductive material. The resistivity of the second conductive material can be less than 20 times the resistivity of the first conductive material.

In one embodiment, a thickness of the first conductive material is greater than a thickness of the second conductive material.

In one embodiment, the method further includes polishing a surface of the non-conductive material and a surface of the first conductive material by way of a chemical-mechanical polishing compatible material.

In one embodiment, the annealing includes annealing the first conductive feature and the second conductive feature at a temperature between 100° C. to 200° C.

In one embodiment, the annealing includes annealing the first conductive feature and the second conductive feature at a temperature between 100° C. to 150° C.

In one embodiment, the annealing forms an alloy between the first and second conductive materials.

In one aspect, a method of forming a bonded structure is disclosed. The method can include providing a first element having a first non-conductive region and a first conductive feature. The first conductive feature includes a first conductive material and a second conductive material. The method can include providing a second element having a second non-conductive region and a second conductive feature, directly bonding the first non-conductive region and the second non-conductive region, and annealing the first conductive feature and the second conductive feature to bond the first conductive material of the first conductive feature and the second conductive feature and to form an alloy between the first and second conductive materials.

In one aspect, an element having a contact surface is disclosed. The element can include a non-conductive region having a cavity extending at least partially through a thickness of the non-conductive region from the contact surface, and a contact pad formed in the cavity, the contact pad including a first conductive material and a second conductive material. The first conductive material is a metal alloying material configured to form an alloy with the second material. The alloy has a unit cell size greater than a unit cell size of the second conductive material. The non-conductive region is configured to directly bond to a non-conductive region of a second element. The contact pad of the element is configured to directly bond to a contact pad of the second element.

In one aspect, an element having a contact surface is disclosed. The element can include a non-conductive region having a cavity extending at least partially through a thickness of the non-conductive region from the contact surface, and a contact pad formed in the cavity. The contact pad includes a first conductive material and a second conductive material. The first conductive material has a unit cell size greater than a unit cell size of the second conductive material. The first conductive material has a coefficient of thermal expansion greater than a coefficient of thermal expansion of the second conductive material. The non-conductive region is configured to directly bond to a non-conductive region of a second element. The contact pad of the element is configured to directly bond to a contact pad of the second element.

In one aspect, an element having a contact surface is disclosed. The element can include a non-conductive region having a cavity extending at least partially through a thickness of the non-conductive region from the contact surface, and a contact pad formed in the cavity, the contact pad including a roughened contact surface. The non-conductive region is configured to directly bond to a non-conductive region of a second element, and the contact pad of the element is configured to directly bond to a contact pad of the second element.

In one embodiment, the roughened contact surface includes spikes.

In one embodiment, the contact pad includes an orthorhombic crystal structure.

In one embodiment, a surface roughness of the contact surface is a range between 3 nm and 100 nm.

In one embodiment, a surface roughness of the contact surface is a range between 3 nm and 50 nm.

In one embodiment, a surface roughness of the contact surface is higher than a roughness of a bonding surface of the non-conductive region.

In one aspect, a bonded structure is disclosed. The bonded structure can include a first element that includes a first non-conductive region having a cavity, and a conductive contact feature disposed in the cavity. The conductive contact feature includes a first conductive material and a second conductive material. The bonded structure can include a second element that is directly bonded to the non-conductive region of the first element. The conductive contact feature includes a unit cell larger than a unit cell of the first conductive material or the second conductive material.

In one embodiment, the conductive contact feature includes an alloy of the first conductive material and the second conductive material.

In one embodiment, the conductive contact feature is directly bonded to a second conductive contact feature of the second element without an intervening adhesive.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. An element having a contact surface, the element comprising:
a non-conductive region having a cavity extending at least partially through a thickness of the non-conductive region from the contact surface; and
a contact pad formed in the cavity, the contact pad including a first conductive material and a second conductive material, the first conductive material having a unit cell size greater than a unit cell size of the second conductive material, the first conductive material being a metal alloying material,
wherein the non-conductive region is configured to directly bond to a non-conductive region of a second element, and the contact pad of the element is configured to directly bond to a contact pad of the second element.

2. The element of claim 1, wherein the unit cell size of the first conductive material is at least 1.3 times greater than the unit cell size of the second conductive material.

3. The element of claim 1, further comprising a barrier layer conformally disposed along surfaces of the cavity, and the first conductive material is disposed between a bottom surface of the cavity and the second conductive material.

4. The element of claim 1, wherein the first conductive material is completely buried under the second conductive material.

5. The element of claim 1, wherein the first conductive material has a characteristic formation temperature of less than 230° C.

6. The element of claim 5, wherein the first conductive material has a characteristic formation temperature of less than 130° C.

7. The element of claim 1, wherein the first conductive material is a metal silicide, and the metal silicide comprises nickel, titanium, or cobalt.

8. The element of claim 1, wherein the first conductive material comprises zinc, titanium, or nickel.

9. The element of claim 1, wherein the second conductive material comprises a face centered cubic structure, and the first conductive material comprises a hexagonal crystal structure.

10. The element of claim 9, wherein the second conductive material comprises copper, and the first conductive material comprises titanium, a resistivity of the first conductive material is greater than a resistivity of the second conductive material.

11. The element of claim 10, wherein the resistivity of the first conductive material is less than 40 times the resistivity of the second conductive material.

12. The element of claim 1, wherein a thickness of the second conductive material is greater than a thickness of the first conductive material.

13. The element of claim 1, wherein the first conductive material is a chemical-mechanical polishing compatible material.

14. A bonded structure comprising:
a first element having a first non-conductive region and a first conductive feature; and
a second element having a second non-conductive region directly bonded to the first non-conductive region, and a second conductive feature directly bonded to the first conductive feature to define a bonded conductive contact,
wherein the bonded conductive contact comprises a first conductive material and a second conductive material, the first conductive material having a unit cell size greater than a unit cell size of the second conductive material, the first conductive material being an alloy comprising the second conductive material.

15. The bonded structure of claim 14, wherein the bonded conductive contact comprises a gradient of alloying element.

16. A bonded structure comprising:
a first element having a first contact surface, the first element comprising:
a first non-conductive region having a first cavity extending at least partially through a thickness of the non-conductive region from the first contact surface; and
a first contact pad formed in the first cavity, the contact pad including a first conductive material and a second conductive material, the first conductive material having a unit cell size greater than a unit cell size of the second conductive material, the first conductive material being a metal alloying material; and
a second element having a second contact surface directly bonded to the first contact surface, the second element comprising:
a second non-conductive region directly bonded to the first non-conductive region; and
a second contact pad directly bonded to the first contact pad.

17. The bonded structure of claim 16, further comprising a barrier layer conformally disposed along surfaces of the first cavity.

18. The bonded structure of claim 16, wherein the first conductive material is disposed between a bottom surface of the first cavity and the second conductive material.

19. The bonded structure of claim 16, wherein the directly bonded first and second contact pads define a bonded conductive contact that comprises an orthorhombic crystal structure, and the directly bonded contact pads comprise copper titanium.

20. The bonded structure of claim 16, wherein the directly bonded first and second contact pads define a bonded conductive contact that comprises a gradient of alloying element.
